(19) United States
(12) Patent Application Publication
(10) Pub. No.: US 2026/0076132 A1
(43) Pub. Date: Mar. 12, 2026

(54) VACUUM HOLE CLEANING APPARATUS, STAGE INCLUDING THE SAME, AND SUBSTRATE TREATMENT APPARATUS INCLUDING THE VACUUM HOLE CLEANING APPARATUS

(71) Applicant: Samsung Electronics Co., Ltd., Suwon-si (KR)

(72) Inventors: YUNSEOK CHOI, Suwon-si (KR); Suk Min Choi, Suwon-si (KR); JUNO PARK, Suwon-si (KR); EUNSEOK LEE, Suwon-si (KR)

(21) Appl. No.: 19/204,744

(22) Filed: May 12, 2025

(30) Foreign Application Priority Data
Sep. 12, 2024 (KR) 10-2024-0124841
Nov. 5, 2024 (KR) 10-2024-0155465

(51) Int. Cl. H01L 21/67; H01L 21/304; H01L 21/683

(52) U.S. Cl. CPC H10P 72/0414; H10P 52/00; H10P 72/0604; H10P 72/78

(57) ABSTRACT

A vacuum hole cleaning apparatus comprising: a hole opening/closing apparatus configured to open and close selected ones of a plurality of vacuum holes formed on a substrate holding surface of a stage, is the hole opening/closing apparatus being detachably attachable to the substrate holding surface; and a cleaning fluid supply configured to supply cleaning fluid to the stage to spray cleaning fluid through the vacuum holes, wherein the hole opening/closing apparatus includes: a first side surface that is adjacent to the substrate holding surface when the hole opening/closing apparatus is attached to the substrate holding surface; and a second side surface facing in an opposite direction to the first side surface, wherein an open area of the hole opening/closing apparatus corresponding to opening target holes of the plurality of vacuum holes, is opened between the first side surface and the second side surface.

### CROSS-REFERENCE TO RELATED APPLICATION

This application claims priority under 35 U.S. C. § 119 to Korean Patent Application No. 10-2024-0124841, filed on Sep. 12, 2024 and Korean Patent Application No. 10-2024-0155465, filed on Nov. 5, 2024 in the Korean Intellectual Property Office, the disclosure of which is incorporated by reference herein in its entirety.

### TECHNICAL FIELD

The present inventive concept relates to a vacuum hole cleaning apparatus for cleaning vacuum holes, and a stage including the same, and a substrate treatment apparatus including the vacuum hole cleaning apparatus, and more particularly, to a vacuum hole cleaning apparatus capable of increasing the pressure of a cleaning fluid supplied to vacuum holes, and a stage including the same, and a substrate treatment apparatus including the vacuum hole cleaning apparatus.

### DISCUSSION OF RELATED ART

Chemical mechanical polishing (CMP) has a cleaning process to remove an abrasive such as slurry remaining on a wafer after a polishing process. This cleaning process may generally include a brush process, a rinse process, a buffing process, etc.

During the processes, the stage supporting the wafer may maintain the substrate in the correct position on the stage by using the vacuum pressure formed in the plurality of vacuum holes formed on the substrate holding surface on which the substrate is placed.

At this time, some or all of the vacuum holes may become narrow or blocked due to deposition of an abrasive inside. Such blockage or narrowing of the vacuum holes may weaken the vacuum pressure of the vacuum holes, causing the wafer to be moved from the correct position.

### SUMMARY

Embodiments of the present disclosure provide a vacuum hole cleaning apparatus capable of cleaning vacuum holes, and a stage including the same, and a substrate treatment apparatus including the vacuum hole cleaning apparatus.

Embodiments of the present disclosure provide a vacuum hole cleaning apparatus capable of increasing the pressure of a cleaning fluid cleaning vacuum holes, a stage including the same, and a substrate treatment apparatus including the vacuum hole cleaning apparatus.

Embodiments of the present disclosure provide a vacuum hole cleaning apparatus capable of increasing the cleaning efficiency of vacuum holes, and a stage including the same, and a substrate treatment apparatus including the vacuum hole cleaning apparatus.

Embodiments of the present disclosure provide a vacuum hole cleaning apparatus capable of preventing a substrate from moving from the correct position during a substrate treatment process, a stage including the same, and a substrate treatment apparatus including the vacuum hole cleaning apparatus.

According to an example embodiment, there is provided a vacuum hole cleaning apparatus comprising: a hole opening/closing apparatus configured to open and close selected ones of a plurality of vacuum holes formed on a substrate holding surface of a stage, and the hole opening/closing apparatus being detachably attachable to the substrate holding surface; and a cleaning fluid supply configured to supply cleaning fluid to the stage to spray cleaning fluid through the vacuum holes, wherein the hole opening/closing apparatus includes: a first side surface that is adjacent to the substrate holding surface when the hole opening/closing apparatus is attached to the substrate holding surface; and a second side surface facing in an opposite direction to the first side surface, wherein an open area of the hole opening/closing apparatus corresponding to opened target holes of the plurality of vacuum holes, is opened between the first side surface and the second side surface.

According to an example embodiment, there is provided a stage comprising: a substrate support body including a substrate holding surface, the substrate support body being configured to mount a substrate thereon, the substrate holding surface having a plurality of vacuum holes; a vacuum pressure forming apparatus configured to form vacuum pressure in the plurality of vacuum holes; and a vacuum hole cleaning apparatus configured to clean the plurality of vacuum holes, wherein the vacuum hole cleaning apparatus includes: a hole opening/closing apparatus configured to open and close selected ones of the plurality of vacuum holes, and the hole opening/closing apparatus being detachably attachable to the substrate holding surface; and a cleaning fluid supply configured to supply cleaning fluid to the stage to spray cleaning fluid through the vacuum holes, wherein the hole opening/closing apparatus includes: a first side surface that is adjacent to the substrate holding surface when the hole opening/closing apparatus is attached to the substrate holding surface; and a second side surface facing in an opposite direction to the first side surface, wherein an open area of the hole opening/closing apparatus corresponding to opened target holes of the plurality of vacuum holes, is opened between the first side surface and the second side surface.

According to an example embodiment, there is provided a substrate treatment apparatus comprising: a stage configured to support a substrate; and a polishing apparatus configured to polish the substrate, wherein the stage includes: a substrate support body including a substrate holding surface, the substrate support body being configured to mount a substrate thereon, the substrate holding surface including a plurality of vacuum holes therein; a vacuum pressure forming apparatus configured to form vacuum pressure in the plurality of vacuum holes; and a vacuum hole cleaning apparatus configured to clean the plurality of vacuum holes, wherein the vacuum hole cleaning apparatus includes: a hole opening/closing apparatus configured to open and close selected ones of the plurality of vacuum holes, and the hole opening/closing apparatus being detachably attachable to the substrate holding surface; and a cleaning fluid supply configured to supply cleaning fluid to the stage to spray cleaning fluid through the vacuum holes, wherein the hole opening/closing apparatus includes: a first side surface that is adjacent to the substrate holding surface when the hole opening/closing apparatus is attached to the substrate holding surface; and a second side surface facing in an opposite direction to the first side surface, wherein an open area of the hole opening/closing apparatus corresponding to opened target holes of the plurality of vacuum holes is opened between the first side surface and the second side surface.

### BRIEF DESCRIPTION OF DRAWINGS

The above and other features of the present disclosure will be more clearly understood from the following detailed description, taken in conjunction with the accompanying drawings.

FIG. 1 is a schematic view illustrating a substrate treatment apparatus according to an example embodiment of the present disclosure.

FIG. 2 is a perspective view illustrating a part of the stage illustrated in FIG. 1.

FIG. 3 is a perspective view illustrating a pressure measurement fastener and a pressure sensor illustrated in FIG. 1.

FIG. 4 is a partial perspective view illustrating a pressure measurement fastener and a pressure sensor installed in an open area illustrated in FIG. 1.

FIG. 5 is an image illustrating an example of the pressure of each of the opened target holes measured by the pressure sensor illustrated in FIG. 1.

FIG. 6 is a perspective view illustrating an individual opening/closing apparatus according to an example embodiment of the present disclosure.

FIG. 7 is a partial cross-sectional view illustrating an individual opening/closing apparatus of FIG. 6 installed in an open area of FIG. 1.

FIG. 8 is a perspective view illustrating a part of a stage according to an example embodiment of the present disclosure.

FIG. 9 is a partial cross-sectional view illustrating a first auxiliary opening/closing apparatus installed in a first open area of FIG. 8.

FIG. 10 is a perspective view illustrating an example in which a first auxiliary opening/closing apparatus is fastened to the second side surface over the first open area of FIG. 8 and a second pressure measurement fastener is fastened to the second side surface over the second open area of FIG. 8.

FIG. 11 is a perspective view illustrating an example in which a first pressure measurement fastener is fastened to the second side surface over the first open area of FIG. 8 and a second auxiliary opening/closing apparatus is fastened to the second open area of FIG. 8.

FIG. 12 is a perspective view illustrating a first individual opening/closing apparatus according to an example embodiment of the present disclosure.

FIG. 13 is a perspective view illustrating a second individual opening/closing apparatus according to an example embodiment of the present disclosure.

### DETAILED DESCRIPTION OF THE EMBODIMENTS

Hereinafter, embodiments of the present disclosure will be described in detail and with sufficient clarity for those skilled in the art to easily implement the invention.

A substrate treatment apparatus according to the present disclosure treats a substrate. The substrate may be provided as a substrate of various types and/or shapes, such as a semiconductor wafer, etc. According to some example embodiments, the substrate treatment apparatus may perform a buffing process to remove an abrasive such as slurry remaining on the wafer after a polishing process using an abrasive. However, the type of process performed by the substrate treatment apparatus according to the present invention is not limited thereto.

Items described in the singular herein may be provided in plural, as can be seen, for example, in the drawings. Thus, the description of a single item that is provided in plural should be understood to be applicable to the remaining plurality of items unless context indicates otherwise.

As used herein the terms “on”, “covering” or “overlapping” are intended to mean that an element is over or aside another element. The elements may be touching or not. For example, there may be layers between layers that are “on” one another. An element “on” or “covering” or “overlapping” another element need not cover an entire top surface of an element below to be considered “on” or “covering” or “overlapping”. The terms are intended to encompass one element “on” or “covering” or “overlapping” all, or any part of, an element below it.

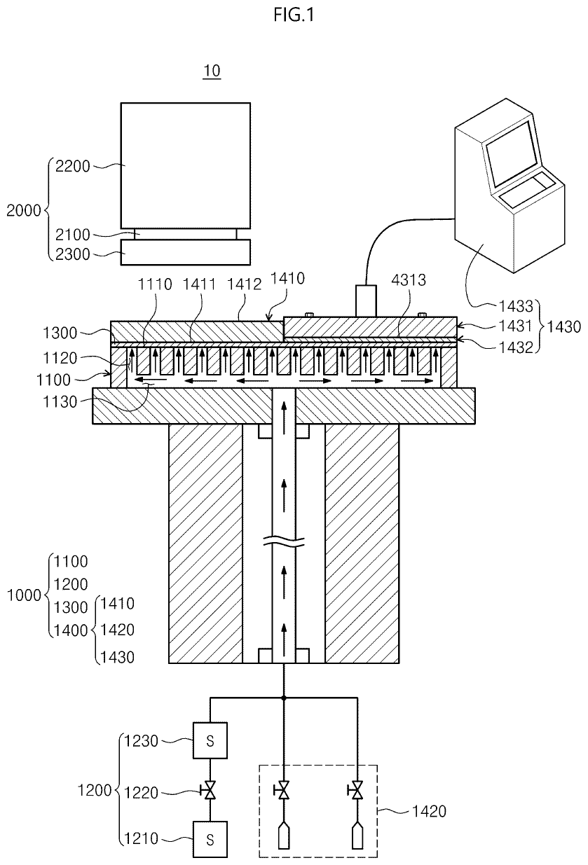

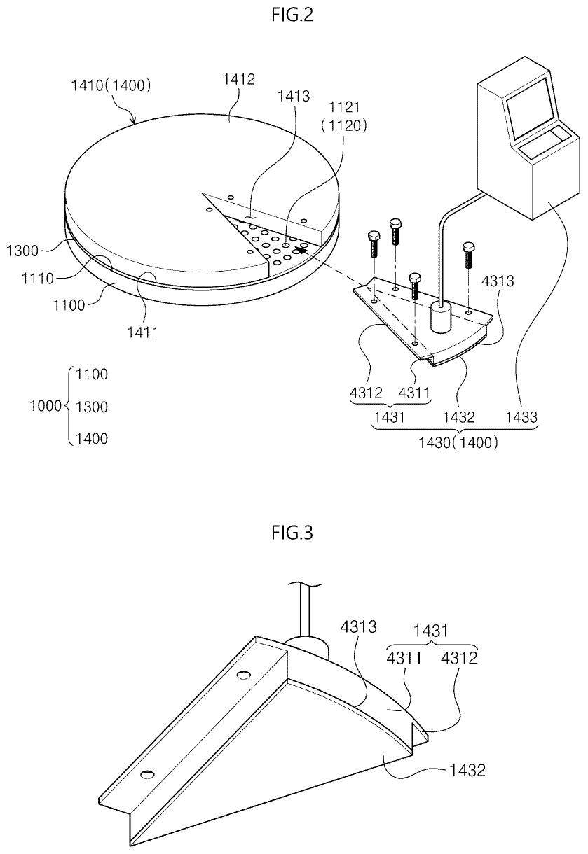

FIG. 1 is a schematic view illustrating a substrate treatment apparatus 10 according to an example embodiment of the present disclosure. FIG. 2 is a perspective view illustrating a part of the stage 1000 illustrated in FIG. 1.

Referring to FIGS. 1 and 2, the substrate treatment apparatus 10 may include a stage 1000 and a polishing apparatus 2000.

The stage 1000 may support a substrate within a chamber where a process for the substrate is performed. The stage 1000 may be a horizontal type in which a substrate holding surface 1110 on which the substrate is mounted (directly or indirectly) is over an upper surface of the substrate support body 1100, or a vertical type in which the substrate holding surface is parallel to a vertical direction. In the following description of this specification, it is assumed that the stage 1000 is a horizontal type. However, the type of the stage 1000 is not limited thereto.

If the stage 1000 is a vertical type, the stage 1000 may further include a substrate clamp that detachably attaches a substrate to a substrate holding surface and/or a hole opening/closing apparatus clamp that detachably attaches a hole opening/closing apparatus 1410 to be described below to the substrate holding surface.

According to some example embodiments, the stage 1000 may include a substrate support body 1100, a vacuum pressure forming apparatus 1200, and a buffing film 1300, and a vacuum hole cleaning apparatus 1400.

The substrate support body 1100 may include a substrate holding surface 1110 on which a substrate is mounted (directly or indirectly) over an upper surface of the substrate support body 1100. A vacuum hole 1120 may be formed in the substrate holding surface 1110. The vacuum holes 1120 may be in multiple numbers. The substrate mounted (directly or indirectly) on the substrate holding surface 1110 may be fixed to the substrate holding surface 1110 by the vacuum pressure formed in the vacuum holes 1120.

The vacuum pressure forming apparatus 1200 may form a vacuum pressure in the vacuum holes 1120. According to some example embodiments, the vacuum pressure forming apparatus 1200 may include a vacuum pump 1210, a vacuum valve 1220, and a vacuum pressure sensing apparatus 1230.

The vacuum pump 1210 may discharge air from the vacuum holes 1120 through the intake path 1130 formed in the substrate support body 1100 to form a vacuum pressure in the vacuum holes 1120. The vacuum valve 1220 may control whether air is discharged from the vacuum holes 1120 by the vacuum pump 1210. The vacuum pressure sensing apparatus 1230 may measure the pressure in the intake path 1130 and the vacuum holes 1120. It may be possible to determine whether the vacuum pressure forming apparatus 1200 is operating normally by the pressure value in the intake path 1130 and the vacuum holes 1120 measured by the vacuum pressure sensing apparatus 1230.

The buffing film 1300 may cover the substrate holding surface 1110. The buffing film 1300 may be made of an elastic material that is impermeable to air. For example, the buffing film 1300 may be made of a rubber or silicone material. By providing the buffing film 1300, the boundary between the substrate placed on the substrate holding surface 1110 and the vacuum holes 1120 are sealed, to make the substrate able to be more firmly fixed to the substrate holding surface 1110. Holes may be formed in the buffing film 1300, each hole in the buffing film being formed at a position corresponding to a position of a vacuum hole 1120

The vacuum hole cleaning apparatus 1400 may clean the vacuum holes 1120. The vacuum hole cleaning apparatus 1400 may discharge foreign substances such as abrasives deposited inside the vacuum holes 1120 to the outside of the vacuum holes 1120. According to some example embodiments, the vacuum hole cleaning apparatus 1400 may include a hole opening/closing apparatus 1410, a cleaning fluid supply 1420, and a pressure measurement apparatus 1430.

The hole opening/closing apparatus 1410 may selectively open and close some of the vacuum holes 1120. The hole opening/closing apparatus 1410 may be detachably attached on the substrate holding surface 1110, which may include for example, being on the buffing film on the substrate holding surface. According to some example embodiments, the hole opening/closing apparatus 1410 may be placed on the substrate holding surface 1110 when the vacuum holes 1120 are cleaned or when the spray pressure of the cleaning fluid sprayed through the vacuum holes 1120 is measured. The hole opening/closing apparatus 1410 may be removed from the substrate holding surface 1110 (e.g. from the buffing film over the substrate holding surface 1110) when other substrate processing processes are performed. For example, the hole opening/closing apparatus 1410 may be taken out of the chamber where the substrate processing process of the substrate treatment apparatus 10 is performed before performing a substrate processing process to perform the substrate processing process.

The hole opening/closing apparatus 1410 may cover the vacuum holes 1120 except for the opened target holes 1121 among the vacuum holes 1120 when viewed from above. The opened target hole 1121 may be some of the vacuum holes 1120 that are not covered by the hole opening/closing apparatus 1410 when the hole opening/closing apparatus 1410 is attached to (directly or indirectly) the substrate holding surface 1110. The hole opening/closing apparatus 1410 may be a plate that may have a uniform thickness. The hole opening/closing apparatus 1410 may include a first side surface 1411 on a side of the hole opening/closing apparatus 1410 that faces the substrate holding surface 1110, and a second side surface 1412. Examples of a hole opening/closing apparatus 1410 plate, may include a plate having one or more openings in the plate, as discussed further below.

The first side surface 1411 of the hole opening/closing apparatus 1410 may be a surface that is adjacent to the substrate holding surface 1110 (which includes being adjacent to the buffing film 1300 therebetween), and blocks the vacuum holes 1120 facing the first side surface 1411 when the hole opening/closing apparatus 1410 is attached to the substrate holding surface 1110. In examples, the first side surface 1411 of the hole opening/closing apparatus 1410 may be flat. The second side surface 1412 of the hole opening/closing apparatus 1410 may be a surface facing the opposite direction from the first side surface 1411 of the hole opening/closing apparatus 1410.

The hole opening/closing apparatus 1410 may include an open area 1413 corresponding to the opened target holes 1121 when the hole opening/closing apparatus 1410 is attached to (directly or indirectly) the substrate holding surface 1110. The open area 1413 may be open between the first side surface 1411 and the second side surface 1412. The hole opening/closing apparatus 1410 may be in a shape corresponding to the substrate holding surface 1110 when looking at the second side surface 1412 of the hole opening/closing apparatus 1410. For example, the hole opening/closing apparatus 1410 may be in a circular shape with an open area 1413 cut off when looking at the second side surface 1412 of the hole opening/closing apparatus 1410 and the substrate holding surface 1110 is circular. However, the shape of the hole opening/closing apparatus 1410 is not limited thereto.

The open area 1413 may be in a fan shape formed by the center of the hole opening/closing apparatus 1410 and two radii that are spread apart from each other and form a certain angle when the hole opening/closing apparatus 1410 is in a circular shape as described herein. Accordingly, in example embodiments, the opened target holes 1121 may be selected depending on the degree to which the hole opening/closing apparatus 1410 is rotated about an axis, relative to the substrate holding surface 1110 with the center of the circular shape as the axis.

The vacuum holes 1120, except the opened target holes 1121, may be blocked when the hole opening/closing apparatus 1410 is mounted on (which includes being attached—directly or indirectly to) the substrate holding surface 1110. In some example embodiments, the open area of the vacuum holes 1120 is reduced compared to when the hole opening/closing apparatus 1410 is not mounted on the substrate holding surface 1110. Therefore, the pressure of the cleaning fluid passing through the vacuum holes 1120 increases compared to when the hole opening/closing apparatus 1410 is not mounted on the substrate holding surface 1110, thereby increasing the cleaning efficiency of the vacuum holes 1120 when the hole opening/closing apparatus 1410 is mounted on the substrate holding surface 1110 and the cleaning fluid is sprayed from the inside of the substrate support body 1100 into the opened target holes 1121 by the cleaning fluid supply 1420. As described above, all the vacuum holes 1120 may be cleaned by rotating the hole opening/closing apparatus 1410 at a certain angle around center (axis) of the hole opening/closing apparatus 1410 to change the opened target holes 1121 and spraying the cleaning fluid through the opened target holes 1121.

According to some example embodiments, the hole opening/closing apparatus 1410 may have sufficient mass to prevent separation from the substrate holding surface 1110 by the pressure of the cleaning fluid within the vacuum holes 1120, and may be made of a material having corrosion resistance to various chemicals used in the substrate treatment apparatus 10. For example, the hole opening/closing apparatus 1410 may be made of stainless steel. However, the material of the hole opening/closing apparatus 1410 is not limited thereto.

A part or all of the outer surface including at least the first side surface 1411 of the hole opening/closing apparatus 1410 may be covered with a material having a high coefficient of friction, elasticity, and air impermeability. For example, the bottom surface or the entire outer surface of the hole opening/closing apparatus 1410 may be coated with a rubber or silicone material. Accordingly, the boundary between the first side surface 1411 of the hole opening/closing apparatus 1410 placed on the substrate holding surface 1110 and the vacuum holes 1120 may be sealed to prevent the cleaning fluid from leaking from the vacuum holes 1120 except the opened target holes 1121. In addition, the hole opening/closing apparatus 1410 may be more efficiently prevented from moving out of the correct position due to the pressure of the cleaning fluid within the vacuum holes 1120.

The cleaning fluid supply 1420 may spray the cleaning fluid through the vacuum holes 1120 to the outside of the stage 1000. According to some example embodiments, the cleaning fluid supply 1420 may supply the cleaning fluid to the vacuum holes 1120 through the intake path 1130. The cleaning fluid may be an inert fluid. For example, the cleaning fluid may be nitrogen (N₂) gas and/or pure water (e.g. deionized DIW).

The pressure measurement apparatus 1430 may measure the spray pressure of the cleaning fluid sprayed through the opened target holes 1121. According to some example embodiments, the pressure measurement apparatus 1430 may include a pressure measurement fastener 1431, a pressure sensor 1432, and a data processor 1433.

The pressure measurement fastener 1431 may be detachably fastened to the second side surface over the open area 1413. According to some example embodiments, the pressure measurement fastener 1431 may include a fastening body 4311 and a fastening fringe 4312.

The fastening body 4311 may block the upper part of the open area 1413. According to some example embodiments, the fastening body 4311 may be configured to engage the open area 1413 when viewed from above.

The fastening fringe 4312 may extend outwardly from the upper end of the side surface of the fastening body 4311. The fastening fringe 4312 may be detachably fastened to the second side surface 1412 of the hole opening/closing apparatus 1410. According to some example embodiments, the fastening fringe 4312 may extend from the fastening body 4311 onto the second side surface 1412 of the hole opening/closing apparatus 1410.

If the open area 1413 of the hole opening/closing apparatus 1410 is in a fan shape when viewed from above, the fastening body 4311 may also be in a fan shape when viewed from above correspondingly. In some example embodiments, the fastening fringe 4312 may extend outwardly from the upper end of both side surfaces corresponding to the radius of the fan shape of the fastening body 4311. The fastening fringe 4312 may be attached and detached from the upper surface of the hole opening/closing apparatus 1410 e.g., by bolts.

The pressure sensor 1432 may detect the spray pressure of the cleaning fluid of each of the opened target holes 1121. The pressure sensor 1432 may be installed on the pressure measurement fastener 1431. The pressure sensor 1432 may transmit the measured pressure value to the data processor 1433.

The data processor 1433 may process the pressure value transmitted from the pressure d sensor 1432 according to each of the opened target holes 1121. The data processor 1433 may visually output the spray pressure of the cleaning fluid for each of the opened target holes 1121 through an output device such as a monitor using the processed pressure value.

The polishing portion 2000 may be configured to polish the substrate supported by the stage 1000. According to some example embodiments, the polishing apparatus 2000 may perform the buffing process on a substrate placed on the stage 1000. The polishing apparatus 2000 may include a rotation shaft 2100, a housing 2200, and a buffing head 2300.

The rotation shaft 2100 may be rotatable in an up-down direction as an axial direction. According to some example embodiments, the rotation shaft 2100 may be rotated by a rotation driver (not illustrated). For example, the rotation driver may be provided in various configurations such as an electric motor that apply a rotation driving force to the rotation shaft 2100. The rotation shaft 2100 may have a cylindrical shape having a longitudinal direction in the up-down direction.

The housing 2200 may have a space inside which the upper part of the rotation shaft 2100 is accommodated. According to some example embodiments, a part of the rotation shaft 2100 including the upper end of the rotation shaft 2100 may be accommodated in the space of the housing 2200. The rotation shaft 2100 may be connected to the rotation driver within the space of the housing 2200. The lower end of the rotation shaft 2100 may be exposed below the housing 2200. The housing 2200 may be a cylindrical shape having a longitudinal direction generally parallel to the axial direction of the rotation shaft 2100 and a diameter larger than that of the rotation shaft 2100.

The buffing head 2300 may buff the substrate by rotating while keeping the lower surface adjacent to the substrate mounted on the substrate holding surface 1110. the upper surface of the buffing head 2300 may be connected to the lower end of the rotation shaft 2100. The axial direction of the buffing head 2300 may be aligned with the axial direction of the rotation shaft 2100. The buffing head 2300 may be rotated by the rotation of the rotation shaft 2100. The buffing head 2300 may have a disk shape having a diameter larger than that of the rotation shaft 2100.

The polishing apparatus 2000 may be movable. For example, the polishing apparatus 2000 may be positioned at the position in which the buffing head 2300 perform buffing on a substrate placed on the substrate holding surface 1110 when performing a buffing process on a substrate. The polishing apparatus 2000 may be positioned at the position in which the buffing head 2300 is positioned out of the substrate holding surface 1110 when cleaning the vacuum hole 1120 or measuring the pressure of the cleaning fluid sprayed from the vacuum hole 1120.

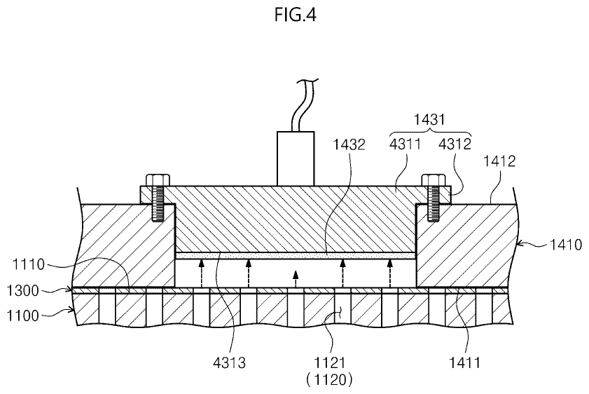

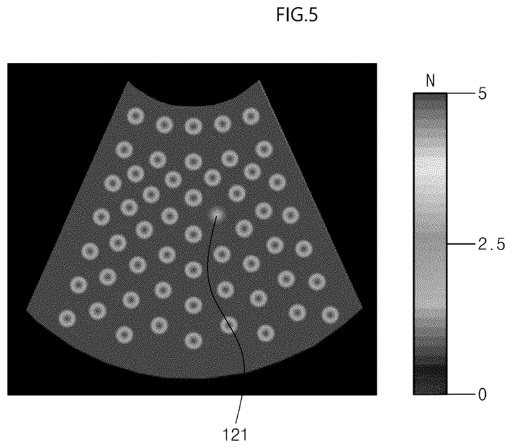

FIG. 3 is a perspective view illustrating a pressure measurement fastener 1431 and a pressure sensor 1432 illustrated in FIG. 1. FIG. 4 is a partial perspective view illustrating a pressure measurement fastener 1431 and a pressure sensor 1432 installed in an open area 1413 illustrated in FIG. 1. FIG. 5 is an image illustrating an example of the pressure of each of the opened target holes 1121 measured by the pressure sensor 1432 illustrated in FIG. 1.

Referring to FIGS. 3 to 5, the pressure sensor 1432 may be installed on the pressure measurement surface 4313 of the pressure measurement fastener 1431. The pressure measurement surface 4313 may be a surface of the pressure measurement fastener 1431 facing the opened target holes 1121 when the pressure measurement fastener 1431 is installed in the open area 1413. According to some example embodiments, the pressure measurement surface 4313 may be the bottom surface of the fastening body 4311. The pressure sensor 1432 may be a sheet or plate covering at least a part of the pressure measurement surface 4313.

The pressure sensor 1432 may be spaced apart through the opened target holes 1121 when the pressure measurement fastener 1431 is fastened to the open area 1413. In order to measure the cleaning fluid spray pressure under the same conditions for each opened target hole 1121, the gap between the pressure sensor 1432 and each opened target hole 1121 may be uniform when the pressure measurement fastener 1431 is fastened to the open area 1413. According to some example embodiments, the pressure measurement surface 4313 and the substrate holding surface 1110 may be in parallel with each other when the pressure measurement fastener 1431 is fastened such that the pressure measurement fastener 1431 covers the open area 1413. The pressure sensor 1432 may be have a uniform thickness.

The pressure sensor 1432 may measure the spray pressure of the cleaning fluid of each of the opened target holes 1121. the measured pressure value of each of the opened target holes 1121 may be output as an image by the data processor 1433 of FIG. 1 as illustrated in FIG. 5. If a part 121 having a lower pressure value than other opened target holes 1121 is found in the output image, it may be determined that all or part of the vacuum hole 1120 corresponding to the part 121 may be blocked. By performing this pressure measurement method while changing the position of the open area 1413, the pressure for all vacuum holes 1120 may be measured to find the blocked vacuum holes 1120.

The hole opening/closing apparatus 1410 may be positioned to make the blocked vacuum holes 1120 are in the open area 1413, and then the vacuum hole cleaning process as described above may be performed to discharge foreign substances in the blocked vacuum holes 1120 when the blocked vacuum holes 1120 are found.

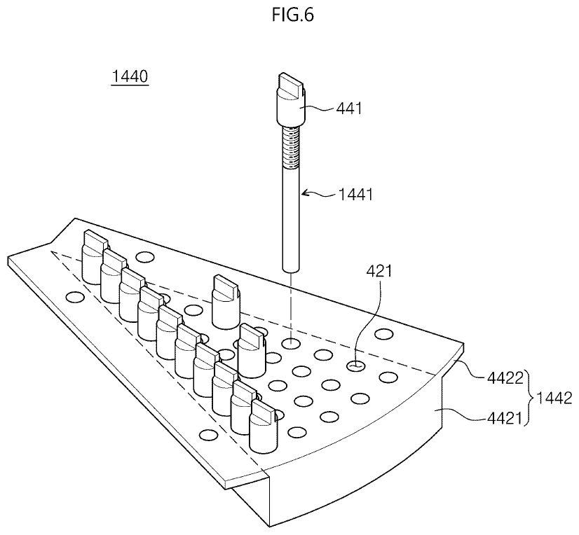

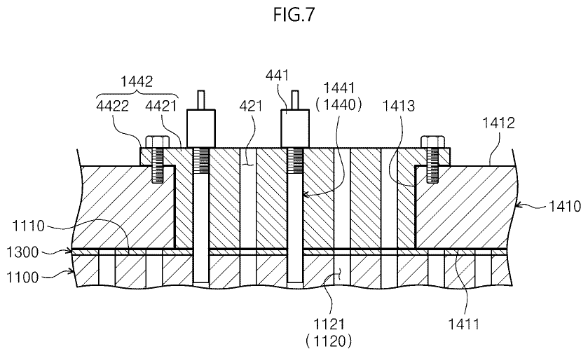

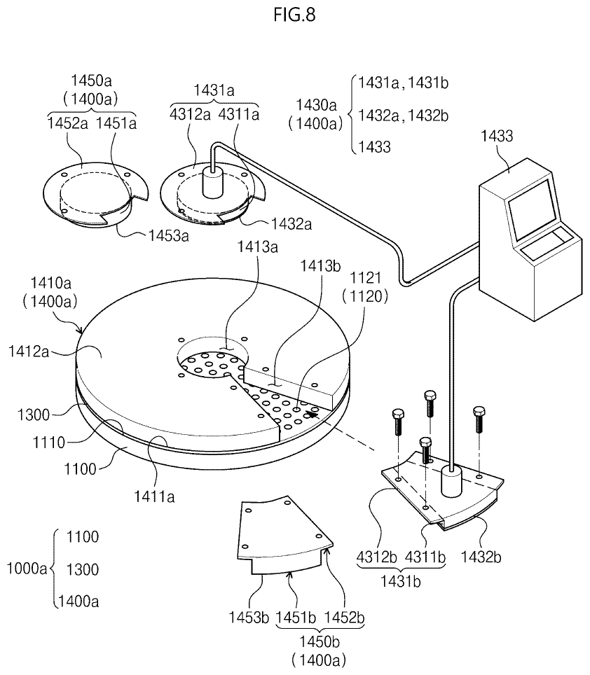

FIG. 6 is a perspective view illustrating an individual opening/closing apparatus 1440 according to an example embodiment of the present disclosure. FIG. 7 is a partial cross-sectional view illustrating an individual opening/closing apparatus 1440 of FIG. 6 installed in an open area 1413 of FIG. 1.

Referring to FIGS. 6 and 7, the vacuum hole cleaning apparatus 1400 of FIG. 1 may further include an individual opening/closing apparatus 1440. The individual opening/closing apparatus 1440 selectively may open and close each of the opened target holes 1121. According to some example embodiments, the individual opening/closing apparatus 1440 may include an individual opening/closing bar 1441 and an opening/closing cover 1442.

The individual opening/closing bar 1441 may have a bar shape. The individual opening/closing bar 1441 may close the opened target holes 1121 by detachably inserting an end of the individual opening/closing bar 1441 into each of the opened target holes 1121. A plurality of the individual opening/closing bars 1441 may open/close a plurality of opened target holes 1121 together.

The opening/closing cover 1442 may be attachable/detachable in the open area 1413. The opening/closing cover 1442 may cover the open area 1413 when the opening/closing cover 1442 is fastened to the open area 1413. Bar penetration holes 4214 may be formed in the opening/closing cover 1442 through which each of the individual opening/closing bars 1441 inserted into the opened target holes 1121 penetrates. According to some example embodiments, the opening/closing cover 1442 may include a cover body 4421 and a cover fringe 4422.

The cover body 4421 may block the upper part of the open area 1413. According to some example embodiments, the cover body 4421 may have a configuration that is engaged with the open area 1413 when viewed from above. The bar penetration holes 421 may be formed by penetrating the cover body 4421 in the vertical direction. In order for the positions of the opened target holes 1121 and the bar penetration holes 421 to correspond to each other, the vacuum holes 1120 may have the same arrangement for each angular range corresponding to the open area 1413.

The cover fringe 4422 may extend outwardly from the upper end of the side surface of the cover body 4421. The cover fringe 4422 may be detachably fastened to the second side surface 1412 of the hole opening/closing apparatus 1410. According to some example embodiments, the cover fringe 4422 may extend from the fastening body 4311 onto the second side surface 1412 of the hole opening/closing apparatus 1410.

If the open area 1413 has a fan shape when viewed from above, the cover body 4421 may also have a fan shape when viewed from above correspondingly. In some example embodiments, the cover fringe 4422 may extend outwardly from the upper end of both side surfaces of the cover body 4421 corresponding to the radius of the fan shape. The cover fringe 4422 may be attached/detached from the upper surface of the hole opening/closing apparatus 1410 by bolts.

Screw surfaces that engaged with each other may be formed on the opposing areas of the individual opening/closing bar 1441 and bar penetration hole 421 respectively, when the individual opening/closing bars 1441 penetrate the bar penetration holes 421 and the end of the individual opening/closing bars 1441 is inserted into the vacuum hole 1120. Accordingly, the individual opening/closing bars 1441 may be screw-connected to the bar penetration holes 421 to make the end of the individual opening/closing bars 1441 be maintained in a state of being inserted into the vacuum holes 1120 even when the cleaning fluid is supplied to the vacuum holes 1120 and pressure is applied to the end of the individual opening/closing bars 1441 in the outward direction of the vacuum holes 1120.

A knob 441 that may be gripped with the user's hand or a tool to easily rotate the individual opening/closing bar 1441 in the longitudinal direction of the individual opening/closing bar 1441 as the axial direction may be at the other end of the individual opening/closing bar 1441.

By providing individual opening/closing bars 1441, the hole opening/closing apparatus 1410 is mounted on the substrate holding surface 1110 to make the blocked vacuum hole 1120 be located within the open area 1413, and the opening/closing cover 1442 is fastened to the open area 1413, and then the individual opening/closing bars 1441 are inserted and fastened into the bar penetration holes 421 to block the opened target holes 1121 except for the blocked vacuum hole 1120, and then a cleaning fluid is supplied to the vacuum holes 1120 to clean the blocked vacuum hole 1120, when a blocked vacuum hole 1120 is found by the pressure measurement apparatus 1430 as illustrated in FIG. 5. At this time, the vacuum holes 1120 except for the vacuum holes 1120 blocked by the individual opening/closing bars 1441 and the hole opening/closing apparatus 1410 are closed, so that a greater cleaning fluid injection pressure may be applied to the blocked vacuum hole 1120. Therefore, the cleaning efficiency of the vacuum hole 1120 may be increased.

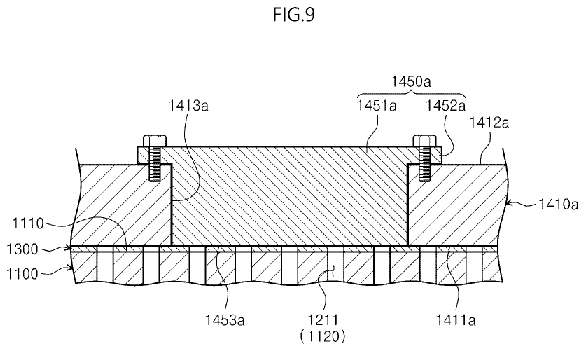

FIG. 8 is a perspective view illustrating a part of a stage 1000a according to an example embodiment of the present disclosure.

Referring to FIG. 8, the open areas 1413a, 1413b may be in various numbers and/or have various structures as needed. The open areas 1413a, 1413b may be provided in multiple numbers. According to some example embodiments, the open areas 1413a, 1413b may include a first open area 1413a and a second open area 1413b. The first open area 1413a and the second open area 1413b may be connected to each other in a horizontal direction.

According to some example embodiments, the first open area 1413a may include the center of the hole opening/closing apparatus 1410a when viewed from above, and may have a circular shape. The second open area 1413b may have a configuration in which a fan shape that extends outwardly from the first open area 1413a and is formed by the center of the hole opening/closing apparatus 1410a and two radii that are spread apart from each other and form a certain angle is cut off in the area overlapping the two radii that are spread apart from each other and form a certain angle when viewed from above.

A vacuum hole 1120 located at the center of the substrate holding surface 1110 or an area adjacent to the center of the substrate holding surface 1110 may be partially covered by the hole opening/closing apparatus 1410 of FIG. 2 due to the fan shape narrowing to the center of the hole opening/closing apparatus 1410 of FIG. 2 when the open area has a complete fan-shape, such as the open area 1431 of FIG. 2. However, as described above, because the first open area 1413a is provided, a vacuum hole 1120 located at the center of the substrate holding surface 1110 or an area adjacent to the center of the substrate holding surface 1110 may be completely exposed to the first open area 1413a.

According to some example embodiments, the vacuum holes 1120 may be cleaned by spraying the cleaning fluid through the opened target holes 1121 when the hole opening/closing apparatus 1410a of which both the first open area 1413a and the second open area 1413b are opened is mounted on the substrate holding surface 1110. In some example embodiments, the method of cleaning all of the vacuum holes 1120 may be the same as or similar to the method of cleaning the vacuum holes 1120 by rotating the hole opening/closing apparatus 1410 of FIG. 1 at a certain interval.

In contrast, the cleaning fluid may be sprayed through the opened target holes 1121, thereby increasing the pressure of the cleaning fluid and enhancing the cleaning efficiency when the hole opening/closing apparatus 1410a of which only one of the first open area 1413a and the second open area 1413b is opened is mounted on the substrate holding surface 1110. In some example embodiments, the auxiliary opening/closing apparatus 1450a, 1450b described below may be used to close the vacuum holes 1120 exposed to the first open area 1413a or the second open area 1413b.

In addition, the pressure measurement fasteners 1431a, 1431b and the pressure sensors 1432a, 1432b may correspond to each of the open areas 1413a, 1413b.

According to some example embodiments, the pressure measurement fasteners 1431a, 1431b may include a first pressure measurement fastener 1431a and a second pressure measurement fastener 1431b. The first pressure measurement fastener 1431a may correspond to the first open area 1413a. The second pressure measurement fastener 1431b may correspond to the second open area 1413b.

The first pressure measurement fastener 1431a may have a structure corresponding to the first open area 1413a. According to some example embodiments, the first pressure measurement fastener 1431a may include a first fastening body 4311a and a first fastening fringe 4312a.

The first fastening body 4311a may have a circular shape corresponding to the shape of the first open area 1413a. The first fastening fringe 4312a may extend outwardly from the upper end of the side surface of the first fastening body 4311a.

The first fastening fringe 4312a may have a configuration of which an area interfering with a configuration fastened to the second open area 1413b is cut off when fastened to the first open area 1413a. For example, the first fastening fringe 4312a may have a configuration in which an area interfering with the second pressure measurement fastener 1431b and a second auxiliary opening/closing apparatus 1450b, described below, fastened to the second open area 1413b is cut off, when the first pressure measurement fastener 1431a is fastened to the second side surface over the first open area 1413a.

The second pressure measurement fastener 1431b may have a configuration corresponding to the second open area 1413b. According to some example embodiments, the second pressure measurement fastener 1431b may include a second fastening body 4311b and a second fastening fringe 4312b.

The second fastening body 4311b may have a fan shape configuration of which a part corresponding to the configuration of the second open area 1413b is cut off. The second fastening fringe 4312b may extend outwardly from the upper end of the outer surface of the second fastening body 4311b.

A part of the second fastening fringe 4312b may not be in an area in which the part may interfere with a configuration fastened to the first open area 1413a. For example, a part of the second fastening fringe 4312b may not be in an area in which the part may interfere with the first pressure measurement fastener 1431a and the first auxiliary opening/closing apparatus 1450a fastened to the first open area 1413a when the second pressure measurement fastener 1431b is fastened to the second open area 1413b.

The pressure sensor 1432a, 1432b may include a first pressure sensor 1432a and a second pressure sensor 1432b. The first pressure sensor 1432a may be installed on the bottom surface of the first fastening body 4311a. The second pressure sensor 1432b may be installed on the bottom surface of the second fastening body 4311b.

According to some example embodiments, the pressure measurement apparatus 1430a may measure the cleaning fluid injection pressure of the opened target holes 1121 exposed to the first open area 1413a and the second open area 1413b together when the first pressure measurement fastener 1431a is fastened to the second side surface over the first open area 1413a and the second pressure measurement fastener 1431b is fastened to the second side surface over the second open area 1413b.

In contrast, the pressure measurement apparatus 1430a may measure the cleaning fluid injection pressure of the opened target holes 1121 exposed to one of the first open area 1413a and the second open area 1413b when only one of the first pressure measurement fastener 1431a and the second pressure measurement fastener 1431b is connected to the second side surface over the first open area 1413a or the second open area 1413b. In some example embodiments, the auxiliary opening/closing apparatus 1450a, 1450b described below may be used.

Other features of the pressure measurement apparatus 1430a according to the present embodiment, such as its configuration, structure, and function, may be identical or similar to the pressure measurement apparatus 1430 of FIG. 1.

FIG. 9 is a partial cross-sectional view illustrating a first auxiliary opening/closing apparatus 1450a installed in a first open area 1413a of FIG. 8.

Referring to FIGS. 8 and 9, the vacuum hole cleaning apparatus 1400a may further include auxiliary opening/closing apparatuses 1450a, 1450b. The auxiliary opening/closing apparatuses 1450a, 1450b may be detachably fastened to each of the open areas 1413a, 1413b.

The auxiliary opening/closing apparatuses 1450a, 1450b may open and close corresponding some of the vacuum holes 1120. For example, the auxiliary opening/closing apparatuses 1450a, 1450b may open and close the vacuum holes 1120 within the corresponding open areas 1413a, 1413b. For example, the auxiliary opening/closing apparatuses 1450a, 1450b may block the vacuum holes 1120 within the corresponding open areas 1413a, 1413b when the auxiliary opening/closing apparatuses 1450a, 1450b are installed in the corresponding open areas 1413a, 1413b. In examples, the auxiliary opening/closing apparatuses 1450a, 1450b may open the vacuum holes 1120 within the corresponding open areas 1413a, 1413b when the auxiliary opening/closing apparatuses 1450a, 1450b are separated from the corresponding open areas 1413a, 1413b.

According to some example embodiments, the auxiliary opening/closing apparatuses 1450a, 1450b may be attached to (directly or indirectly) one of the first open area 1413a and the second open area 1413b where the pressure measurement apparatus 1430a does not measure the cleaning fluid injection pressure of the vacuum holes 1120, and close the vacuum holes 1120 exposed to the one. In addition, the auxiliary opening/closing apparatus 1450a, 1450b may be fastened to one of the first open area 1413a and the second open area 1413b where cleaning for the vacuum holes 1120 using cleaning fluid is not performed, and close the vacuum holes 1120 exposed to the one.

The auxiliary opening/closing apparatuses 1450a, 1450b may be corresponding to each of the open areas 1413a, 1413b when a plurality of open areas 1413a, 1413b are provided. Each of the auxiliary opening/closing apparatuses 1450a, 1450b may include an auxiliary fastening body 1451a, 1451b and an auxiliary fastening fringe 1452a, 1452b. According to some example embodiments, the auxiliary opening/closing apparatuses 1450a, 1450b may include a first auxiliary opening/closing apparatus 1450a and a second auxiliary opening/closing apparatus 1450b. The first auxiliary opening/closing apparatus 1450a may correspond to the first open area 1413a. In examples, the second auxiliary opening/closing apparatus 1450b may correspond to the second open area 1413b.

The first auxiliary opening/closing apparatus 1450a may have a configuration corresponding to the first open area 1413a. According to some example embodiments, the first auxiliary opening/closing apparatus 1450a may include a first auxiliary fastening body 1451a and a first auxiliary fastening fringe 1452a.

The first auxiliary fastening body 1451a may have a circular shape corresponding to the structure of the first open area 1413a. The bottom surface of the first auxiliary fastening body 1451a may be parallel to the substrate holding surface 1110 and adjacent to the substrate holding surface 1110 to block to block the opened target holes 1121 exposed to the first open area 1413a when the first auxiliary opening/closing apparatus 1450a is fastened to the first open area 1413a. The first auxiliary fastening body 1451a may be made of the same material as the hole opening/closing apparatus 1410 of FIG. 1 described above. In addition, at least a part of the outer surface including the bottom surface of the first auxiliary fastening body 1451a may be coated with the same material as the coating material of the hole opening/closing apparatus 1410 of FIG. 1.

The first auxiliary fastening fringe 1452a may extend outwardly from the upper end of the side surface of the first auxiliary fastening body 1451a. The first auxiliary fastening fringe 1452a may have a configuration in which a part interfering with a configuration fastened to the second open area 1413b when the first auxiliary opening/closing apparatus 1450a is fastened to the first open area 1413a is cut off. For example, the first auxiliary fastening fringe 1452a may have a configuration in which a part of the first auxiliary fastening fringe 1452a interfering with the second pressure measurement fastener 1431b or the second auxiliary opening/closing apparatus 1450b fastened to the second open area 1413b is cut off when the first auxiliary opening/closing apparatus 1450a is fastened to the first open area 1413a. The first auxiliary fastening fringe 1452a may be detachably attached to (directly or indirectly) the second side surface 1412a of the hole opening/closing apparatus 1410a by bolts.

The second auxiliary fastening apparatus 1450b may have a configuration corresponding to the second open area 1413b. According to some example embodiments, the second auxiliary fastening apparatus 1450b may include a second auxiliary fastening body 1451b and a second auxiliary fastening fringe 1452b.

The second auxiliary fastening body 1451b may have a fan shape in which a part of the second auxiliary fastening body 1451b corresponding to the configuration of the second open area 1413b is cut off. The bottom surface of the second auxiliary fastening body 1451b may be parallel to the substrate holding surface 1110 and adjacent to the substrate holding surface 1110 to block the opened target holes 1121 exposed to the second open area 1413b when the second auxiliary opening/closing apparatus 1450b is fastened to the second open area 1413b. The second auxiliary fastening body 1451b may be made of the same material as the hole opening/closing apparatus 1410 of FIG. 1 described above. In addition, at least a part of the outer surface including the bottom surface of the second auxiliary fastening body 1451b may be coated with the same material as the coating material of the hole opening/closing apparatus 1410 of FIG. 2.

The second auxiliary fastening fringe 1452b may extend outwardly from the upper end of the outer surface of the second auxiliary fastening body 1451b. A part of the second auxiliary fastening fringe 1452b that may interfere with a configuration fastened to the first open area 1413a may not be provided. For example, a part of the second auxiliary fastening fringe 1452b that may interfere with the first pressure measurement fastener 1431a and the first auxiliary opening/closing apparatus 1450a fastened to the first open area 1413a may not be provided when the second auxiliary opening/closing apparatus 1450b is fastened to the second open area 1413b. The second auxiliary fastening fringe 1452b may be detachably attached from the second side surface 1412a of the hole opening/closing apparatus 1410a by bolts.

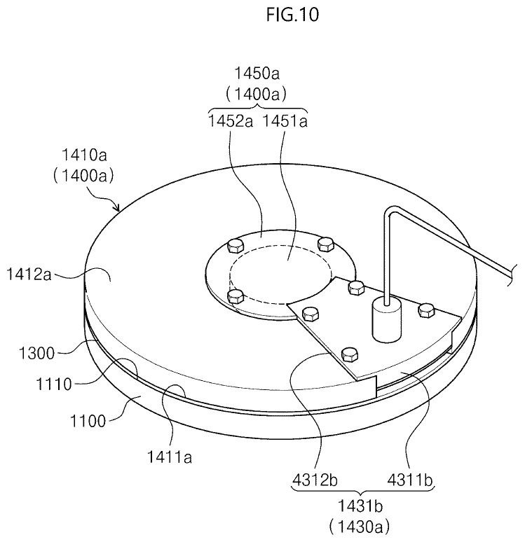

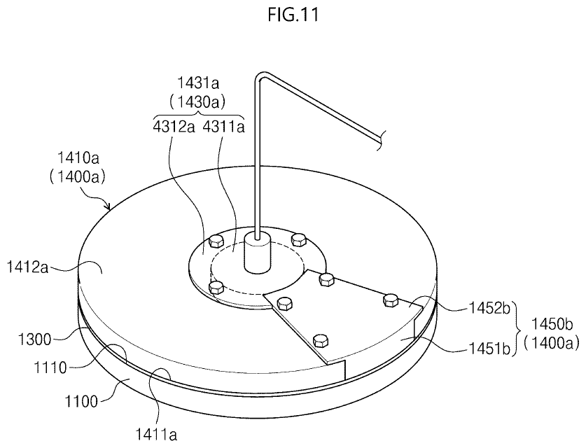

FIG. 10 is a perspective view illustrating an example in which a first auxiliary opening/closing apparatus 1450a is fastened to the first open area 1413a of FIG. 8 and a second pressure measurement fastener 1431b is fastened to the second side surface over the second open area 1413b of FIG. 8. FIG. 11 is a perspective view illustrating an example in which a first pressure measurement fastener 1431a is fastened to the second side surface over the first open area 1413a of FIG. 8 and a second auxiliary opening/closing apparatus 1450b is fastened to the second open area 1413b of FIG. 8.

Referring to FIGS. 10 and 11, the first pressure measurement fastener 1431a or the second pressure measurement fastener 1431b may be fastened to the second side surface over one or both of the first open area 1413a and the second open area 1413b where the pressure of the cleaning fluid injection of the vacuum holes 1120 is to be measured, and a first auxiliary opening/closing apparatus 1450a or a second auxiliary opening/closing apparatus 1450b is fastened to one of the first open area 1413a and the second open area 1413b where the pressure of the cleaning fluid injection of the vacuum holes 1120 is not to be measured, thereby enabling a higher cleaning fluid injection pressure to be measured compared to a case where the cleaning fluid injection pressure of the opened target holes 1121 exposed to the first open area 1413a and the second open area 1413b is measured together.

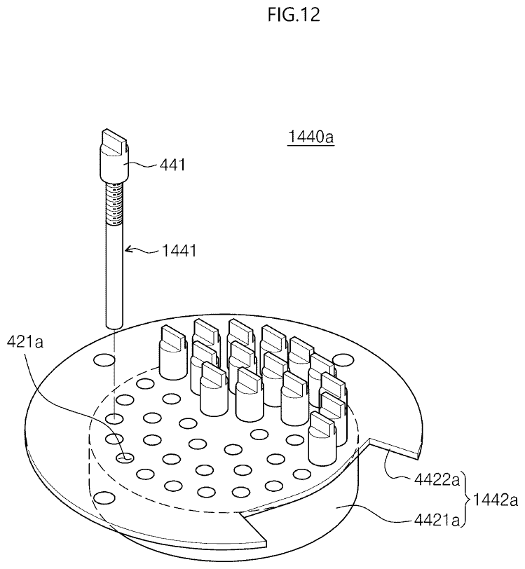

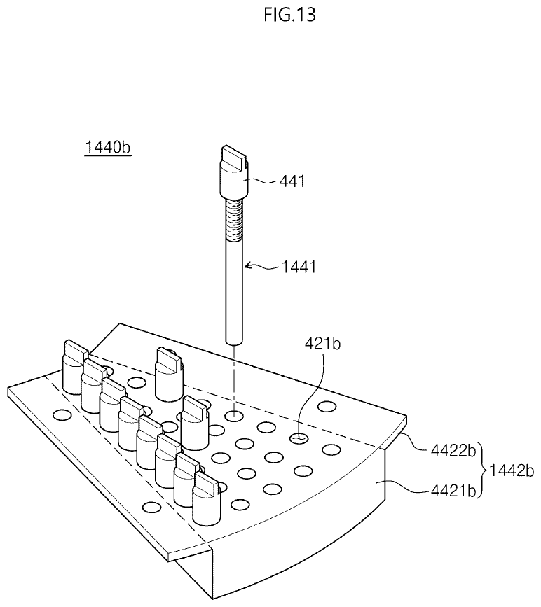

FIG. 12 is a perspective view illustrating a first individual opening/closing apparatus 1440a according to an example embodiment of the present disclosure. FIG. 13 is a perspective view illustrating a second individual opening/closing apparatus 1440b according to an example embodiment of the present disclosure.

Referring to FIGS. 8, 12, and 13, the vacuum hole cleaning apparatus 1400a of FIG. 8 may further include individual opening/closing apparatuses 1440a, 1440b. The individual opening/closing apparatuses 1440a, 1440b may correspond to each of the open areas 1413a, 1413b. According to an embodiment, the individual opening/closing apparatuses 1440a, 1440b may include a first individual opening/closing apparatus 1440a and a second individual opening/closing apparatus 1440b.

The first individual opening/closing apparatus 1440a selectively may open and close each of the opened target holes 1121 exposed to the first open area 1413a. According to some example embodiments, the first individual opening/closing apparatus 1440a may include an individual opening/closing bar 1441 and a first opening/closing cover 1442a.

The first opening/closing cover 1442a may include a first cover body 4421a and a first cover fringe 4422a.

The first cover body 4421a may have a configuration corresponding to the configuration of the first open area 1413a. For example, the first cover body 4421a may have a circular shape corresponding to the first open area 1413a. Bar penetration holes 421 may be formed in the first cover body 4421a.

The first cover fringe 4422a may extend outward from the upper end of the side surface of the first cover body 4421a. A part of the first cover fringe 4422a interfering with the above-described configurations fastened to the second open area 1413b and the second individual opening/closing apparatus 1440b may be cut off. The first cover fringe 4422a may be detachably attached to (directly or indirectly) the second side surface 1412a of the hole opening/closing apparatus 1410a by bolts.

The second individual opening/closing apparatus 1440b selectively may open and close each of the opened target holes 1121 exposed to the second open area 1413b. According to some example embodiments, the second individual opening/closing apparatus 1440b may include an individual opening/closing bar 1441 and a second opening/closing cover 1442b.

The second opening/closing cover 1442b may include a second cover body 4421b and a second cover fringe 4422b.

The second cover body 4421b may have a configuration corresponding to the configuration of the second open area 1413b. For example, the second cover body 4421b may have a fan shape of which a part corresponding to the second open area 1413b is cut off. Bar penetration holes 421 may be formed in the second cover body 4421b.

The second cover fringe 4422b extends outwardly from the upper end of the side surface of the second cover body 4421b. A part of the second cover fringe 4422b that may interfere with the above-described configurations that are fastened to the second open area 1413b and the first individual opening/closing apparatus 1440a may not be provided. The second cover fringe 4422b may be detachably attached to (directly or indirectly) the second side surface 1412a of the hole opening/closing apparatus 1410a by bolts.

The individual opening/closing bar 1441 of the first individual opening/closing apparatus 1440a and the individual opening/closing bar 1441 of the second individual opening/closing apparatus 1440b may have the same configuration as the individual opening/closing bar 1441 of FIG. 6.

Other features of the configuration, and function of the first individual opening/closing apparatus 1440a and the second individual opening/closing apparatus 1440b may be identical or similar to the features of the opened target holes 1121 of the individual opening/closing apparatus 1440 of FIG. 6. The vacuum holes 1120 except the vacuum holes 1120 to be cleaned where foreign substances are judged to remain inside may be closed by the first individual opening/closing apparatus 1440a, the second individual opening/closing apparatus 1440b, the first auxiliary opening/closing apparatus 1450a, or the second auxiliary opening/closing apparatus 1450b, thereby increasing the pressure of the cleaning fluid when cleaning is performed by spraying the cleaning fluid through the vacuum holes 1120.

Other features such as configuration and function of the substrate treatment apparatus to which the configurations of FIGS. 8 to 13 are applied may be identical or similar to the features of the substrate treatment apparatus 10 of FIGS. 1 to 7.

As described above, the vacuum hole cleaning apparatus 1400, 1400a, the stage 1000, 1000a including the same, and the substrate treatment apparatus including the vacuum hole cleaning apparatus 1400, 1400a according to the embodiments of the present disclosure may clean the vacuum holes 1120 using a cleaning fluid.

In addition, the vacuum hole cleaning apparatus 1400, 1400a, the stage 1000, 1000a including the same, and the substrate treatment apparatus including the vacuum hole cleaning apparatus 1400, 1400a according to the embodiments of the present disclosure may increase the pressure of the cleaning fluid during cleaning by opening and closing selected vacuum holes 1120, thereby increasing the cleaning efficiency of the vacuum holes 1120.

In addition, the vacuum hole cleaning apparatus 1400, 1400a, the stage 1000, 1000a including the same, and the substrate treatment apparatus including the vacuum hole cleaning apparatus 1400, 1400a according to the embodiments of the present disclosure may effectively discharge foreign substances remaining in the vacuum holes 1120 by cleaning the vacuum holes 1120 with high cleaning efficiency, thereby maintaining the pressure of the vacuum holes 1120 evenly, thereby preventing the substrate from moving out of the correct position during the substrate treatment process.

While the present disclosure has been described with reference to embodiments thereof, it will be apparent to those of ordinary skill in the art that various changes and modifications can be made thereto without departing from the spirit and scope of the present disclosure as set forth in the following claims.

What is claimed is:

1. A vacuum hole cleaning apparatus comprising:
a hole opening/closing apparatus configured to open and close selected ones of a plurality of vacuum holes formed on a substrate holding surface of a stage, the hole opening/closing apparatus being detachably attachable to the substrate holding surface; and
a cleaning fluid supply configured to supply cleaning fluid to the stage to spray cleaning fluid through the vacuum holes,
wherein the hole opening/closing apparatus includes:
a first side surface that is adjacent to the substrate holding surface when the hole opening/closing apparatus is attached to the substrate holding surface; and
a second side surface facing in an opposite direction to the first side surface,
wherein an open area of the hole opening/closing apparatus corresponding to opening target holes of the plurality of vacuum holes, is opened between the first side surface and the second side surface.

2. The vacuum hole cleaning apparatus of claim 1 further comprising:
a pressure measurement apparatus configured to measure spray pressures of cleaning fluid sprayed through the opening target holes,
wherein the pressure measurement apparatus includes:
a pressure measurement fastener detachably fastened to the second side surface over the open area; and
a pressure sensor on a pressure measurement surface of the pressure measurement fastener that faces the opening target holes and is configured to detect a spray pressure of each opening target hole of the opening target holes.

3. The vacuum hole cleaning apparatus of claim 2,
wherein the pressure measurement fastener comprises
a fastening body blocking an upper part of the open area of the hole opening/closing apparatus; and
a fastening fringe extending outwardly from an upper end of a side surface of the fastening body, the fastening fringe being detachably fastened to the second side surface of the hole opening/closing apparatus.

4. The vacuum hole cleaning apparatus of claim 2,
wherein the open area comprises a plurality of open areas, and
wherein the pressure measurement fastener and the pressure sensor are over each open area.

5. The vacuum hole cleaning apparatus of claim 4, further comprising:
an auxiliary opening/closing apparatus detachably fastened to the second side surface over each open area of the open areas and opening and closing corresponding selected ones of the vacuum holes.

6. The vacuum hole cleaning apparatus of claim 5,
wherein each auxiliary opening/closing apparatus includes:
an auxiliary fastening body that has a surface adjacent to the substrate holding surface, configured to block corresponding selected ones of the vacuum holes when the auxiliary fastening body is over the open area; and
an auxiliary fastening fringe that extends outwardly from an upper end of a side surface of the auxiliary fastening body and is detachably fastened to the second side surface.

7. The vacuum hole cleaning apparatus of claim 1, further comprising:
an individual opening/closing apparatus that selectively opens and closes each opening target hole of the opening target holes.

8. The vacuum hole cleaning apparatus of claim 7,
wherein the individual opening/closing apparatus includes:
individual opening/closing bars each opening/closing bar including an end that is detachably inserted into a corresponding opening target hole; and
an opening/closing cover that is detachably attached to the first side surface over the open area, covers the open area when being fastened to the first side surface, and has bar penetration holes formed therein, through which each individual opening/closing bar inserted into a corresponding opening target hole penetrates.

9. The vacuum hole cleaning apparatus of claim 8,
wherein screw surfaces that engage with each other are formed on opposing areas of individual opening/closing bars and corresponding bar penetration holes.

10. A stage comprising:
a substrate support body including a substrate holding surface, the substrate support body being configured to mount a substrate thereon, the substrate holding surface having a plurality of vacuum holes;
a vacuum pressure forming apparatus configured to form vacuum pressure in the plurality of vacuum holes; and
a vacuum hole cleaning apparatus configured to clean the plurality of vacuum holes,
wherein the vacuum hole cleaning apparatus includes:
a hole opening/closing apparatus configured to open and close selected ones of the plurality of the vacuum holes, and the hole opening/closing apparatus being detachably attachable to the substrate holding surface; and
a cleaning fluid supply configured to supply cleaning fluid to the stage to spray cleaning fluid through the vacuum holes,
wherein the hole opening/closing apparatus includes:
a first side surface that is adjacent to the substrate holding surface when the hole opening/closing apparatus is attached to the substrate holding surface; and
a second side surface facing in an opposite direction to the first side surface,
wherein an open area of the hole opening/closing apparatus corresponding to opening target holes of the plurality of vacuum holes, is opened between the first side surface and the second side surface.

11. The stage of claim 10,
wherein the vacuum hole cleaning apparatus further includes:
a pressure measurement apparatus configured to measure spray pressures of cleaning fluid sprayed through the opening target holes,
wherein the pressure measurement apparatus includes:
a pressure measurement fastener detachably fastened to the second side surface over the open area; and
a pressure sensor on a pressure measurement surface of the pressure measurement fastener that faces the opening target holes and is configured to detect a spray pressure of each opening target hole of the opening target holes.

12. The stage of claim 11,
wherein the open area comprises a plurality of open areas, and
wherein the pressure measurement fastener and the pressure sensor are over each open area.

13. The stage of claim 12,
wherein the vacuum hole cleaning apparatus further includes an auxiliary opening/closing apparatus detachably fastened to the second side surface over each open area of the open areas and opening and closing corresponding selected the vacuum holes.

14. The stage of claim 10,
wherein the vacuum hole cleaning apparatus further includes an individual opening/closing apparatus that selectively opens and closes each opening target hole of the opening target holes,
wherein the individual opening/closing apparatus includes:
individual opening/closing bars each opening/closing bar including an end that is detachably inserted into a corresponding opening target holes; and
an opening/closing cover that is detachably attached to the first side surface of the hole opening/closing apparatus over the open area, covers the open area when being fastened to the first side surface of the hole opening/closing apparatus, and has bar penetration holes formed therein through which each opening/closing bar inserted into a corresponding opening target holes penetrates.

15. The stage of claim 14,
wherein screw surfaces that engage with each other are formed on opposing areas of individual opening/closing bars and corresponding bar penetration holes.

16. A substrate treatment apparatus comprising:
a stage configured to support a substrate; and
a polishing apparatus configured to polish the substrate,
wherein the stage includes:
a substrate support body including a substrate holding surface, the substrate support body being configured to mount a substrate thereon, the substrate holding surface including a plurality of vacuum holes therein;
a vacuum pressure forming apparatus configured to form vacuum pressure in the plurality of vacuum holes; and
a vacuum hole cleaning apparatus configured to clean the plurality of vacuum holes,
wherein the vacuum hole cleaning apparatus includes:
a hole opening/closing apparatus configured to open and close selected ones of the plurality of vacuum holes, and the hole opening/closing apparatus being detachably attachable to the substrate holding surface; and
a cleaning fluid supply configured to supply cleaning fluid to the stage to spray cleaning fluid through the vacuum holes,
wherein the hole opening/closing apparatus includes:
a first side surface that is adjacent to the substrate holding surface when the hole opening/closing apparatus is attached to the substrate holding surface; and
a second side surface facing in an opposite direction to the first side surface,
wherein an open area of the hole opening/closing apparatus corresponding to opening target holes of the plurality of vacuum holes, is opened between the first side surface and the second side surface.

17. The substrate treatment apparatus of claim 16,
wherein the vacuum hole cleaning apparatus further includes:
a pressure measurement apparatus configured to measure spray pressures of cleaning fluid sprayed through the opening target holes,
wherein the pressure measurement apparatus includes:
a pressure measurement fastener detachably fastened to the second side surface over the open area; and
a pressure sensor on a pressure measurement surface of the pressure measurement fastener that faces the opening target holes and is configured to detect a spray pressure of each opening target hole of the opening target holes.

18. The substrate treatment apparatus of claim 17,
wherein the open area comprises a plurality of open areas,
wherein the pressure measurement fastener and the pressure sensor are each over an open area of the plurality of open areas.
wherein the vacuum hole cleaning apparatus further includes an auxiliary opening/closing apparatus detachably fastened to the second side surface over each open area of the open areas and opening and closing selected ones of the vacuum holes.

19. The substrate treatment apparatus of claim 16,
wherein the vacuum hole cleaning apparatus further includes an individual opening/closing apparatus configured to selectively open and close each opening target hole of the opening target holes,
wherein the individual opening/closing apparatus includes:
individual opening/closing bars each opening/closing bar including an end that is detachably inserted into a corresponding opening target hole; and
an opening/closing cover that is detachably attached to the first side surface of the hole opening/closing apparatus over open area, covers the open area when being fastened to the first side surface of the hole opening/closing apparatus, and has bar penetration holes formed therein, through which each individual opening/closing bar inserted into a corresponding opening target hole penetrates.

20. The substrate treatment apparatus of claim 19,
wherein screw surfaces that engage with each other are formed on opposing areas of individual opening/closing bars and corresponding bar penetration holes.
